(19) United States
(12) Patent Application Publication
(10) Pub. No.: US 2025/0180854 A1
(43) Pub. Date: Jun. 5, 2025

(54) LENS MODULE AND ELECTRONIC DEVICE HAVING THE SAME

(71) Applicant: TRIPLE WIN TECHNOLOGY(SHENZHEN) CO.LTD., Shenzhen (CN)

(72) Inventors: YU-XIANG YAN, New Taipei (TW); DING FENG, Jincheng (CN); JIA-QI WU, Jincheng (CN); RUI ZHANG, Jincheng (CN); JING-WEI LI, Shenzhen (CN)

(21) Appl. No.: 18/649,947

(22) Filed: Apr. 29, 2024

(30) Foreign Application Priority Data
Dec. 4, 2023 (CN) 202323306535.5

(51) Int. Cl. G02B 7/02; H05K 1/02; H05K 1/14

(52) U.S. Cl. CPC G02B 7/025; H05K 1/0274; H05K 1/141; H05K 2201/10121

(57) ABSTRACT

The present disclosure provides a lens module and an electronic device with lens module. The lens module includes a lens, a bracket, a connecting board, a circuit board and a first adhesive layer. The lens is connected on the bracket. The connecting board has a first surface facing the bracket. A first groove is formed on the first surface of the connecting board. The circuit board is disposed in the groove and protrudes from the first surface. A photosensitive film is disposed on the circuit board. The bracket is connected on the connecting board through the first adhesive layer.

### FIELD

The subject matter relates to imaging, and more particularly, to a lens module and an electronic device having the lens module.

### BACKGROUND

Lens modules are used in various electronic devices, such as cameras, mobile phones, monitors, and recorders. The lens module usually includes a bracket, a lens component, and a circuit board. A size of the lens may be large, and the dimensional tolerances of the lens may also be large. During the active alignment (AA) process, collision may happen between the bracket and the circuit board, thereby causing damages to the circuit board.

Therefore, there is room for improvement in the art.

### BRIEF DESCRIPTION OF THE DRAWINGS

Implementations of the present technology will now be described, by way of example only, with reference to the attached figures.

FIG. 1 is a diagrammatic view of a lens module in related arts.

FIG. 2 is a diagrammatic view of a lens module according to an embodiment of the present disclosure.

FIG. 3 is an exploded view of the lens module shown in FIG. 2.

FIG. 4 is another exploded view of the lens module shown in FIG. 2.

FIG. 5 is a cross-sectional view of the lens module along a view line V-V shown in FIG. 2.

FIG. 6 is an enlarged view of portion A shown in FIG. 5.

FIG. 7 is an enlarged view of portion B shown in FIG. 5.

FIG. 8 is a diagrammatic view of an electronic device according to an embodiment of the present disclosure.

### DETAILED DESCRIPTION

It will be appreciated that for simplicity and clarity of illustration, where appropriate, reference numerals have been repeated among the different FIG.s to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

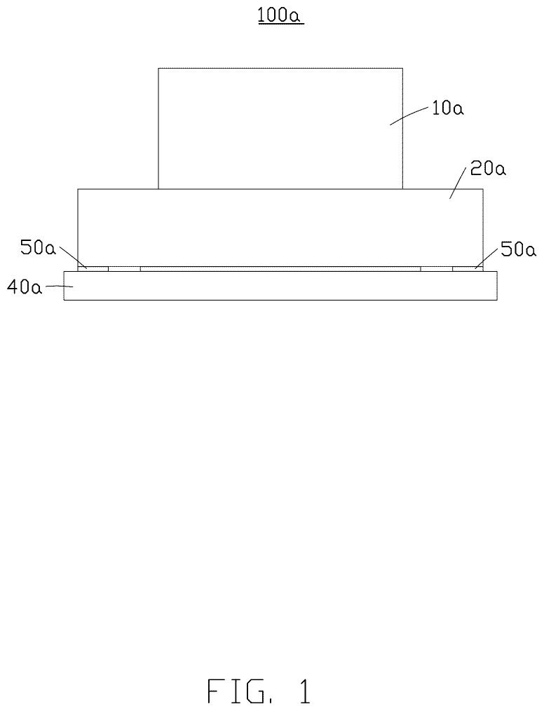

Referring to FIG. 1, in related art, a lens module 100a includes a lens 10a, a bracket 20a, a circuit board 40a, and a first adhesive layer 50a. The lens 10a is connected on the bracket 20a. The bracket 20a is connected on the circuit board 40a through the first adhesive layer 50a. When a height of the lens module 100a remains unchanged, the greater the dimensional tolerance of the lens 10a, the smaller the space for setting the first adhesive layer 50a, and the smaller the thickness of the first adhesive layer 50a. During the active alignment (AA) process, collision may happen between the bracket 20a and the circuit board 40a, which may cause damages to the circuit board 40a or electronic components on the circuit board 40a.

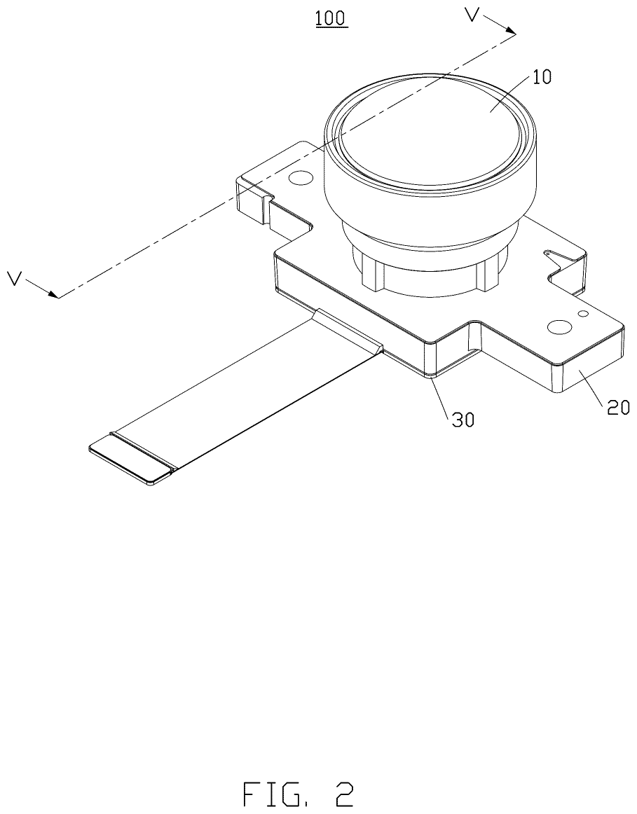

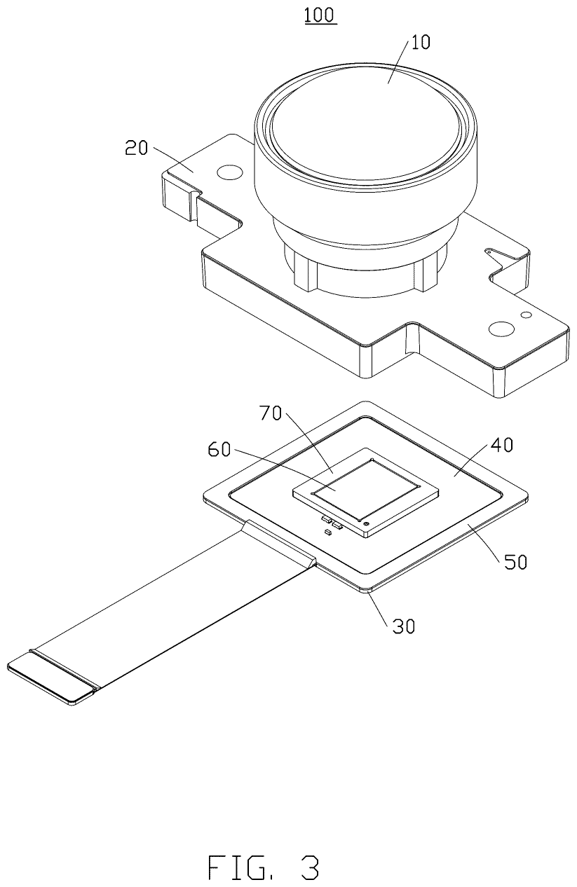

Referring to FIGS. 2 to 4, a lens module 100 is provided according to an embodiment of the present disclosure. The lens module 100 includes a lens 10, a bracket 20, a connecting board 30, a circuit board 40 and a first adhesive layer 50. The connecting board 30 includes a first surface 31, and the first surface 31 defines a first groove 32. The circuit board 40 is at least partially disposed in the first groove 32 and protrudes from the first surface 31. The photosensitive film 41 is disposed on the circuit board 40. The first adhesive layer 50 is disposed on the first surface 31 besides the first groove 32. The bracket 20 is adhered to the first adhesive layer 50. The bracket 20 is connected on the connecting board 30 through the first adhesive layer 50. The lens 10 is mounted on the bracket 20 and faces the photosensitive film 41.

In the lens module 100, the circuit board 40 is partially disposed in the first groove 32 and protrudes from the first surface 31, so that the first surface 31 is lower than the circuit board 40, increasing a space between the first surface 31 and the bracket 20. Thus, a thickness of the first adhesive layer 50 disposed between the first surface 31 and the bracket 20 can be increased. The bracket 20 is adhered to the first surface 31 of the connecting board 30 through the first adhesive layer 50, reducing a risk of collision between the bracket 20 and the circuit board 40 without increasing the overall height of the lens module 100.

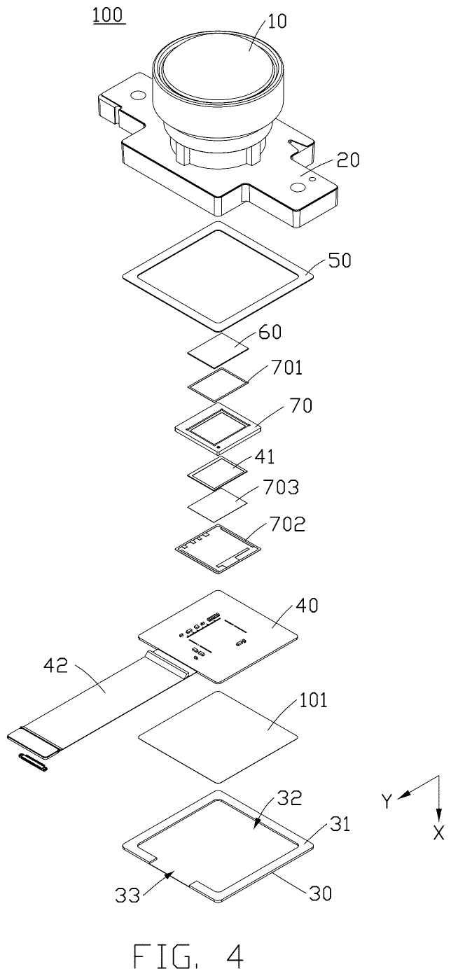

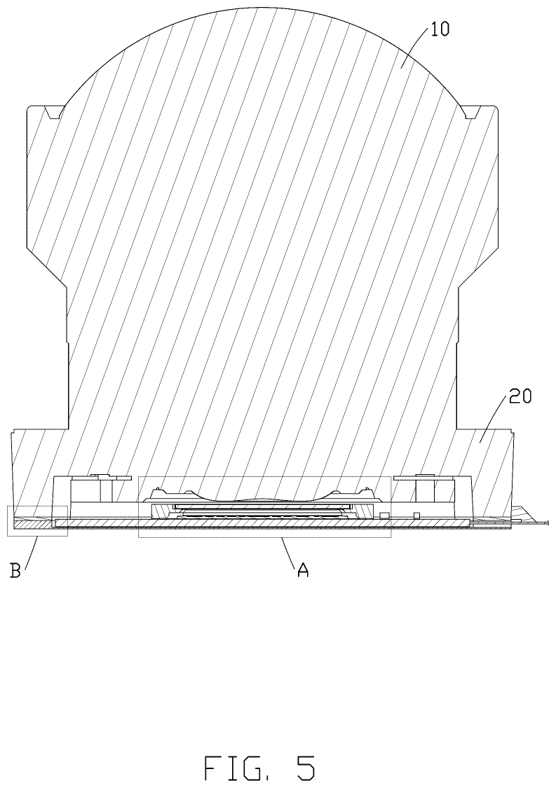

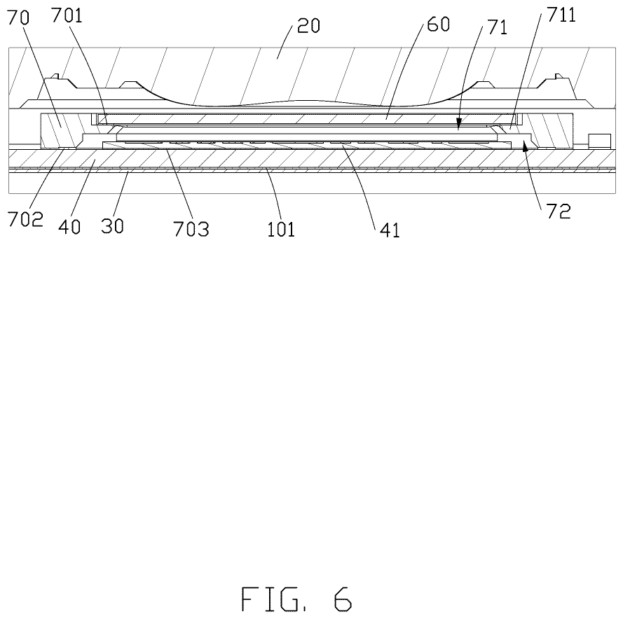

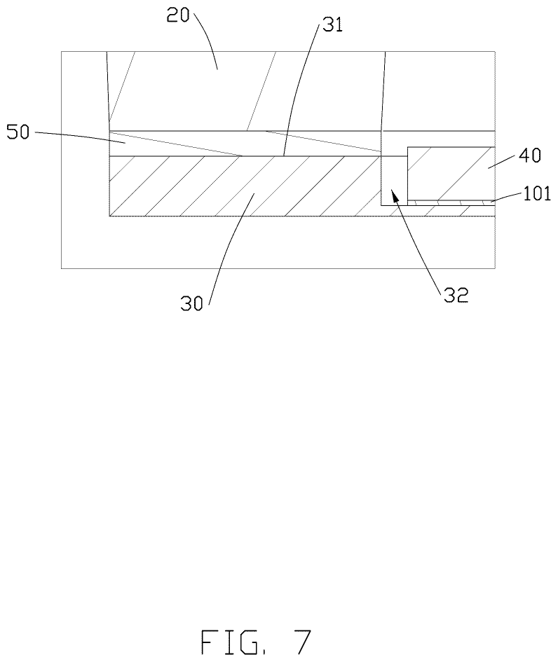

Referring to FIGS. 4 to 7, in at least one embodiment, the lens module 100 includes a second adhesive layer 101. The second adhesive layer 101 is disposed in the first groove 32. The circuit board 40 is connected on the second adhesive layer 101. A surface of the circuit board 40 facing away from the bracket 20 is connected to the second adhesive layer 101. The second adhesive layer 101 can fix the circuit board 40 in the first groove 32.

In at least one embodiment, a sum of a thickness of the second adhesive layer 101 and a thickness of the circuit board 40 is greater than a depth of the first groove 32, so that the circuit board 40 can protrude from the first surface 31.

In at least one embodiment, a height of the circuit board 40 protruding from the first surface 31 is equal to the thickness of the first adhesive layer 50.

In at least one embodiment, the connecting board 30 includes a metal plate, which can dissipate heat generated by the lens module 100. In an embodiment, the metal plate is made of a stainless steel.

In at least one embodiment, the bracket 20 and the circuit board 40 are arranged along a first direction X. The connecting plate 30 has a notch 33 communicating with the first groove 32, and the notch 33 penetrates through the connecting plate 30 along a second direction Y. The circuit board 40 includes a flat cable 42. The flat cable 42 passes through the notch 33 and exits the first groove 32 to connect to other electronic components. The first direction X is perpendicular to the second direction Y.

In at least one embodiment, the lens module 100 further includes an optical filter 60. The optical filter 60 disposed between the lens 10 and the photosensitive film 41, which is beneficial for improving the clarity of the lens 10.

In at least one embodiment, the lens module 100 further includes a connecting base 70. The connecting base 70 is disposed and connected on the circuit board 40. An opening 71 is formed on the connecting base 70. The connecting base 70 has a flange 711 protruding from the inner wall of the opening 71. The optical filter 60 is disposed on the flange 711 and do not protrude from a surface of the connecting base 70, which can reduce the height of the lens module 100.

In at least one embodiment, the lens module 100 further includes a third adhesive layer 701 disposed on the flange 711. The optical filter 60 is connected to the third adhesive layer 701. The optical filter 60 is fixed on the flange 711 through the third adhesive layer 701.

In at least one embodiment, the lens module 100 further includes a fourth adhesive layer 702. The connecting base 70 is adhered to the circuit board 40 through the fourth adhesive layer 702.

In at least one embodiment, the lens module 100 further includes a fifth adhesive layer 703. The photosensitive film 41 is adhered to the circuit board 40 through the fifth adhesive layer 703.

In at least one embodiment, a second groove 72 is formed on a side of the connecting base 70 facing away from the optical filter 60. The photosensitive film 41 is disposed in the second groove 72, which can reduce the height of the lens module 100.

With the above configuration, the circuit board 40 is partially disposed in the first groove 32 and protrudes from the first surface 31, so that the first surface 31 is lower than the circuit board 40, increasing the space between the first surface 31 and the bracket 20. Thus, the thickness of the first adhesive layer 50 between the first surface 31 and the bracket 20 is increased. The bracket 20 is adhered to the first surface 31 of the connecting board 30 through the first adhesive layer 50, reducing the risk of collision between the bracket 20 and the circuit board 40, and the overall height of the lens module 100 can be reduced.

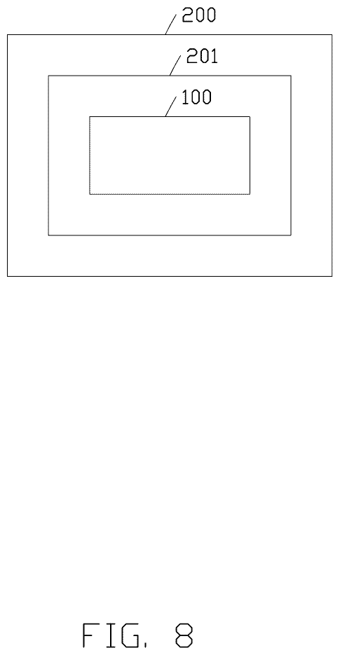

Referring to FIG. 8, an electronic device 200 is also provided according to an embodiment of the present disclosure. The electronic device 200 includes a casing 301 and the lens module 100 mounted on the casing 301. The electronic device 200 may be, but is not limited to, a face recognition device, a security monitor camera, a digital camera, a network camera, a video phone, a video doorbell, a digital telescope, a license plate recognition camera.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present exemplary embodiments, to the full extent indicated by the plain meaning of the terms in which the appended claims are expressed.

What is claimed is:

1. A lens module comprising:
a connecting board comprising a first surface, and the first surface defining a first groove;
a circuit board at least partially disposed in the first groove and protruding from the first surface;
a photosensitive film disposed on the circuit board;
a first adhesive layer disposed on the first surface besides the first groove;
a bracket adhered to the first adhesive layer; and
a lens mounted on the bracket and facing the photosensitive film.

2. The lens module according to claim 1, further comprising a second adhesive layer disposed in the first groove, wherein the circuit board is adhered to the second adhesive layer.

3. The lens module according to claim 2, wherein a sum of a thickness of the second adhesive layer and a thickness of the circuit board is greater than a depth of the first groove.

4. The lens module according to claim 3, wherein a height of the circuit board protruding from the first surface is equal to the thickness of the first adhesive layer.

5. The lens module according to claim 1, further comprising an optical filter disposed between the lens and the photosensitive film.

6. The lens module according to claim 5, further comprising a connecting base fixed on the circuit board, wherein the connecting base defines an opening, the connecting base comprising a flange protruding from an inner wall of the opening, and the optical filter is fixed on the flange.

7. The lens module according to claim 6, further comprising a third adhesive layer disposed on the flange, wherein the optical filter is adhered to the third adhesive layer.

8. The lens module according to claim 6, further comprising a fourth adhesive layer, wherein the connecting base is adhered to the circuit board through the fourth adhesive layer.

9. The lens module according to claim 1, wherein the connecting board comprised a metal plate.

10. The lens module according to claim 1, wherein the connecting board further defines a notch communicating with the first groove, the circuit board comprises a cable, and the cable passes through the notch.

11. An electronic device comprising:
a casing; and
a lens module mounted to the casing, the lens module comprising:
a connecting board comprising a first surface, and the first surface defining a first groove;
a circuit board at least partially disposed in the first groove and protruding from the first surface;
a photosensitive film disposed on the circuit board;
a first adhesive layer disposed on the first surface besides the first groove;
a bracket adhered to the first adhesive layer; and
a lens mounted on the bracket and facing the photosensitive film.

12. The electronic device according to claim 11, further comprising a second adhesive layer disposed in the first groove, wherein the circuit board is adhered to the second adhesive layer.

13. The electronic device according to claim 12, wherein a sum of a thickness of the second adhesive layer and a thickness of the circuit board is greater than a depth of the first groove.

14. The electronic device according to claim 13, wherein a height of the circuit board protruding from the first surface is equal to the thickness of the first adhesive layer.

15. The electronic device according to claim 11, further comprising an optical filter disposed between the lens and the photosensitive film.

16. The electronic device according to claim 15, further comprising a connecting base fixed on the circuit board, wherein the connecting base defines an opening, the connecting base comprising a flange protruding from an inner wall of the opening, and the optical filter is fixed on the flange.

17. The electronic device according to claim 16, further comprising a third adhesive layer disposed on the flange, wherein the optical filter is adhered to the third adhesive layer.

18. The electronic device according to claim 16, further comprising a fourth adhesive layer, wherein the connecting base is adhered to the circuit board through the fourth adhesive layer.

19. The electronic device according to claim 11, wherein the connecting board comprised a metal plate.

20. The electronic device according to claim 11, wherein the connecting board further defines a notch communicating with the first groove, the circuit board comprises a cable, and the cable passes through the notch.
